(19) United States
(12) Patent Application Publication
(10) Pub. No.: US 2013/0248963 A1
(43) Pub. Date: Sep. 26, 2013

(54) NONVOLATILE SEMICONDUCTOR MEMORY DEVICE AND MANUFACTURING METHOD OF THE SAME

(71) Applicant: KABUSHIKI KAISHA TOSHIBA, Tokyo (JP)

(72) Inventor: Hideto TAKEKIDA, Aichi (JP)

(73) Assignee: KABUSHIKI KAISHA TOSHIBA, Tokyo (JP)

(21) Appl. No.: 13/784,621

(22) Filed: Mar. 4, 2013

(30) Foreign Application Priority Data
Mar. 14, 2012 (JP) 2012057218

(51) Int. Cl. H01L 27/105

(52) U.S. Cl. CPC H01L 27/1052
USPC 257/315; 438/258

(57) ABSTRACT

A memory cell array including a plurality of memory cell units arrayed in a matrix configuration along a first direction and a second direction which is perpendicular direction to the first direction, each memory cell unit including a plurality of memory cell transistors, a first select gate transistor and a second select gate transistor, word lines extending to the first direction, and a first insulating film formed on an upper surface of the memory cell array, a first embedded wiring layer embedded in the first embedded wiring layer, the first embedded wiring layer including a wiring portion commonly connected to a source region of each first select gate transistor, wherein the first embedded wiring layer has an inclined pattern which extends in a direction not parallel to either of the first and the second directions.

### CROSS-REFERENCE TO RELATED APPLICATION

This application is based upon and claims the benefit of priority from Japanese Patent Application No. 2012-057218, filed Mar. 14, 2012; the entire contents of which are incorporated herein by reference.

### FIELD

Embodiments described herein relate to a nonvolatile semiconductor memory device and manufacturing method thereof.

### BACKGROUND

For nonvolatile semiconductor memory devices, such as NAND-type flash memory, as device features become smaller, the electrical interference between adjacent memory cells becomes large. The interference between the adjacent memory cells may be caused by increases in capacitance coupling between adjacent memory cells. Capacitance coupling between adjacent memory cells increases the voltage threshold required for writing data to memory cells. Because the threshold increases due to coupling between the adjacent memory cells separated by an insulating film, it is preferred for the dielectric constant of the insulating film to be as low as possible to reduce the capacitance between the adjacent cells. Because the effective dielectric constant of the insulating film is a function of film density and the dielectric constant is a product of the dielectric constant of vacuum (empty space) and the specific dielectric constant of the film material, it is possible to decrease the effective dielectric constant between two memory cells by arranging an insulating film including a void or a gap (air gap) in the layer to reduce the effective dielectric constant.

However, although the air gap structure can improve the memory cell performance characteristics (e.g., reduce capacitive coupling), it is nevertheless a vacant space that may collapse during fabrication steps. Of specific concern are forces due to compression and shear stress during the CMP (chemical mechanical polishing) treatment process used, for example, for flattening an interlayer insulating film and an embedded wiring layer. In this case, because in the CMP treatment of the wiring layer, the cutting rate for the metal is lower than that of the interlayer insulating film, the interlayer film side becomes a concave shape. As a result, the slurry stays in the concave interlayer insulating film, and stress is generated. Here, the highest shear stress results when an over-polishing treatment is carried out to help prevent residual voids where both the metal wiring layer and the interlayer insulating film are exposed at the same time. The shear stress is generated due to the difference in the frictional force between metal and the insulating layer and this is further enhanced by the trapping of the slurry in portions of the wiring pattern that form right angles (sharp corners) in the wiring pattern.

### DESCRIPTION OF THE DRAWINGS

FIG. 1 is one example of a schematic diagram illustrating the electrical configuration of a portion of the memory cell region of a NAND-type flash memory according to an embodiment.

FIG. 2A is one example of a schematic plane view illustrating the structure of a portion of the memory cell region. FIG. 2B is one example of a diagram illustrating the pattern of a first embedded wiring layer.

FIG. 3 is one example of a schematic view of a cross-section taken across A-A in FIGS. 2A and 2B.

FIG. 4 is one example of a schematic view of a cross-section taken across A-A in FIGS. 2A and 2B that illustrates a step of the manufacturing process.

FIG. 5 is one example of a schematic view of a cross-section taken across A-A in FIGS. 2A and 2B that illustrates a step of the manufacturing process.

FIG. 6 is one example of a schematic view of a cross-section taken across A-A in FIGS. 2A and 2B that illustrates a step of the manufacturing process.

FIG. 7 is one example of a schematic view of a cross-section taken across A-A in FIGS. 2A and 2B that illustrates a step of the manufacturing process.

FIG. 8 is one example of a schematic view of a cross-section taken across A-A in FIGS. 2A and 2B that illustrates a step of the manufacturing process.

### DETAILED DESCRIPTION

Embodiments provide a nonvolatile semiconductor memory device, which includes an air gap arranged between the gate electrodes of the memory cell transistors and an embedded wiring layer formed using a CMP treatment, and a manufacturing method of such a memory device.

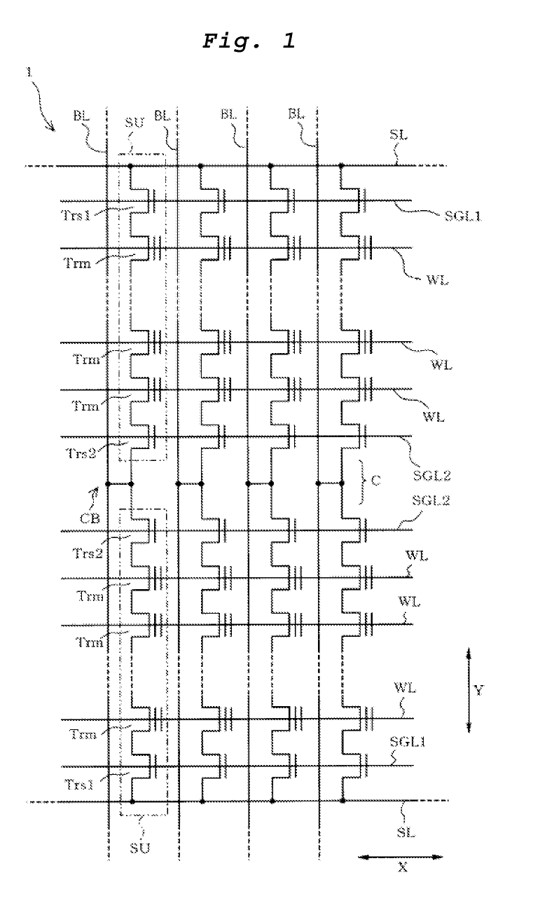

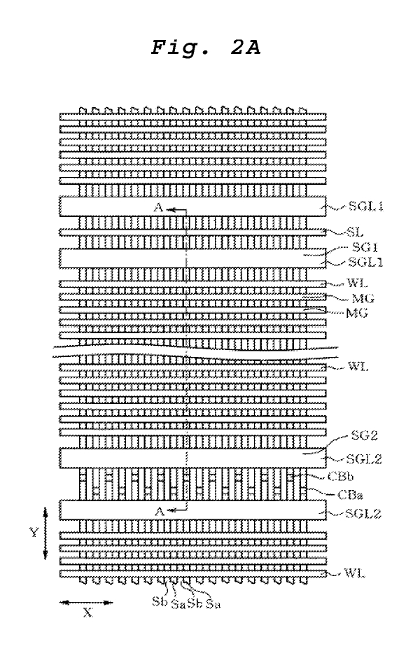

In general, embodiments are incorporated in a NAND-type flash memory and will be explained with reference to FIG. 1 to FIG. 8. Here, the drawings are schematic diagrams, so that the relationship between the thickness and the planar dimensions, as well as the ratio of the thicknesses of the various layers, is not to actual scale. As far as the up/down directions and left/right direction are concerned, they merely illustrate the relative directions when the side of the semiconductor substrate on which the memory device is being formed is the upper side of the substrate. Such a convention may not in agreement with the directions determined by reference to the direction of gravity.

The present disclosure describes a nonvolatile semiconductor memory device comprising a memory cell array including a plurality of memory cell units arrayed in a matrix configuration along a first direction and a second direction which is perpendicular direction to the first direction, each memory cell unit including a plurality of memory cell transistors connected in series, a first select gate transistor connected to a first end of the memory cell unit, and a second select gate transistor connected to a second end of the memory cell unit word lines extending to the first direction, each of which is commonly connected to control gate electrodes of memory transistors disposed to the first direction, and a first insulating film formed on an upper surface of the memory cell array, a first embedded wiring layer embedded in the first embedded wiring layer, the first embedded wiring layer including a wiring portion commonly connected to a source region of each first select gate transistor. The first embedded wiring layer has an inclined pattern which extends in a direction not parallel to either of the first and the second directions.

Also, the present disclosure describes a manufacturing method of the nonvolatile semiconductor memory device having the following steps of operation: forming a memory cell array having a plurality of memory cell units arrayed in a matrix in a first direction and a second direction, each memory cell unit having a plurality of memory cell transistors connected in series, a first select gate transistor connected to a first end of the memory cell unit, and a second select gate transistor connected to a second end of the memory cell unit; forming a first insulating film on an upper surface of the memory cell array; forming trenches in the first insulating film, the trenches formed an inclined pattern which extends in a direction not parallel to either of the first and the second directions; forming a metal film on the first insulating film, the metal film filling the trenches; and polishing the metal film to remove the metal film except portions in the trenches.

First of all, the electrical configuration of the NAND-type flash memory in the present embodiment will be explained. FIG. 1 is one example of an equivalent circuit diagram of the memory cell array formed in the memory cell region of a NAND-type flash memory device 1.

The NAND-type flash memory device 1 has NAND cell units SU as the memory cell units formed in a matrix form in its memory cell array. Here, each NAND cell unit has a first select gate transistor Trs1 and a second select gate transistor Trs2, and plural (e.g., 64) memory cell transistors Trm connected in series between the select gate transistors Trs1 and Trs2. In the NAND cell unit SU, the plural memory cell transistors Trm adjacent each other share the source/drain region.

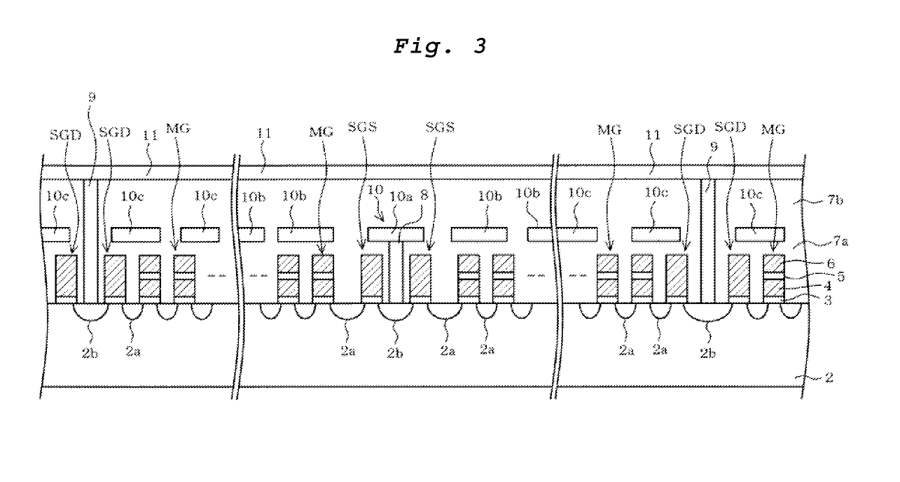

The memory cell transistors Trm arranged in the X-direction (word line direction) in FIG. 1 are commonly connected by word line WL that connects their control gate electrodes. The first select gate transistors Trs1 arranged in the X-direction shown in FIG. 1 are commonly connected by the select gate line SGL1, and the second select gate transistors Trs2 are commonly connected by the select gate line SGL2. The first select gate transistor Trs1 is connected via a source region to the source line SL extending in the X-direction in FIG. 1. This source line SL is formed in a first embedded wiring layer (depicted in FIG. 3 as layer 10a-10c). The drain region of the second select gate transistor Trs2 is connected to the bit line contact CB. This bit line contact CB is connected to the bit line BL extending in the Y-direction (bit line direction) orthogonal to the X-direction in FIG. 1.

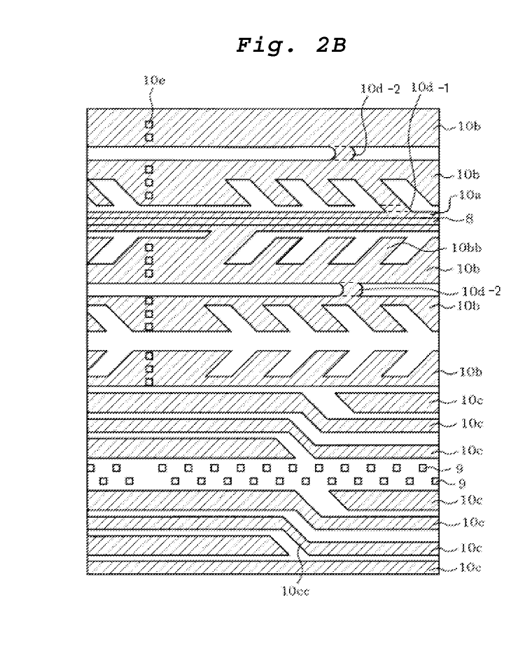

FIG. 2A is one example of a diagram illustrating the layout pattern of a portion of the memory cell region. As shown in FIG. 2A, in the memory cell region of a silicon substrate 2, the element separating region Sb (including a STI (shallow trench isolation) structure with an insulating film embedded in a trenche) is formed extending in the Y-direction shown in the drawing. Several element separating regions Sb are formed with a prescribed interval in the X-direction shown in the drawing. As a result, the element region Sa is formed extending in the Y-direction, and several element regions Sa are formed separated from each other in the X-direction in the surface layer portion of the silicon substrate 2.

The word lines WL are formed extending in the direction (X-direction in FIG. 2A) crossing perpendicular to the element regions Sa. Multiple word lines WL are formed with a prescribed interval in the Y-direction. On the element regions Sa where word lines WL cross the element region Sa, the gate electrodes MG of the memory cell transistors Trm are formed.

Several memory cell transistors Trm adjacent to each other in the Y-direction become a portion of a NAND column (memory cell string). The first select gate transistors Trs1 are arranged adjacent to the memory cell transistors Trm at a first end portion of the NAND column. Multiple first select gate transistors Trs1 are arranged in the X-direction and the gate electrodes SGS of multiple first select gate transistors Trs1 are electrically connected by the select gate line SGL1. The gate electrodes SGS are formed where the select gate line SGL1 and the element regions Sa cross each other.

Similarly, multiple second select gate transistors Trs2 are arranged in the X-direction as shown in the drawing, and the gate electrodes SGD of multiple second select gate transistors Trs2 are electrically connected by the select gate line SGL2. The gate electrodes SGD are formed in the portions where the select gate line SGL2 and the element regions Sa cross each other.

The bit line contacts CBa and CBb are formed on the element regions Sa between adjacent gate electrodes SGD-SGD, respectively. Here, the bit line contacts CBa are arranged in a zigzag configuration so that the bit line contact CBb is near the gate electrode SGD on the other side. Using this arrangement it is possible to arrange the bit line contacts CBa and CBb so that the distance between the adjacent bit line contacts CBa and CBb is larger, making it possible to alleviate the trouble of short circuit between the bit line contacts CBa and CBb.

FIG. 3 is a schematic cross-sectional view taken across A-A in FIG. 2A in the memory cell region. As shown in FIG. 3, on the upper surface of the silicon substrate 2, the various gate electrodes MG and SGS and SGD of the memory cell transistors Trm and the first and second select gate transistors Trs1 and Trs2 are formed on a gate insulating film 3. For example, the gate insulating film 3 is a silicon oxide film. The memory cell transistors Trm include the gate electrode MG and source/drain regions 2a formed adjacent the gate insulating film 3 in the substrate 2. Multiple memory cell transistors Trm are formed adjacent each other in the Y-direction. A pair of the first select gate transistors Trs1 adjacent each other in the end portions of the memory cell transistors Trm are formed on one end side, and a pair of the second select gate transistors Trs2 are formed on the other end side.

The memory cell transistor Trm has the following parts disposed on the gate insulating film 3: a polysilicon film 4 as the charge accumulating layer (floating gate electrode), an inter-electrode insulating film 5, and a polysilicon film 6 as the control gate electrode. There may also be a silicide film or the like with a low resistance formed on the polysilicon film 6. The inter-electrode insulating film 5 may be an ONO (oxide-nitride-oxide) film, or NONON (nitride-oxide-nitride-oxide-nitride film or other insulating film with a high dielectric constant.

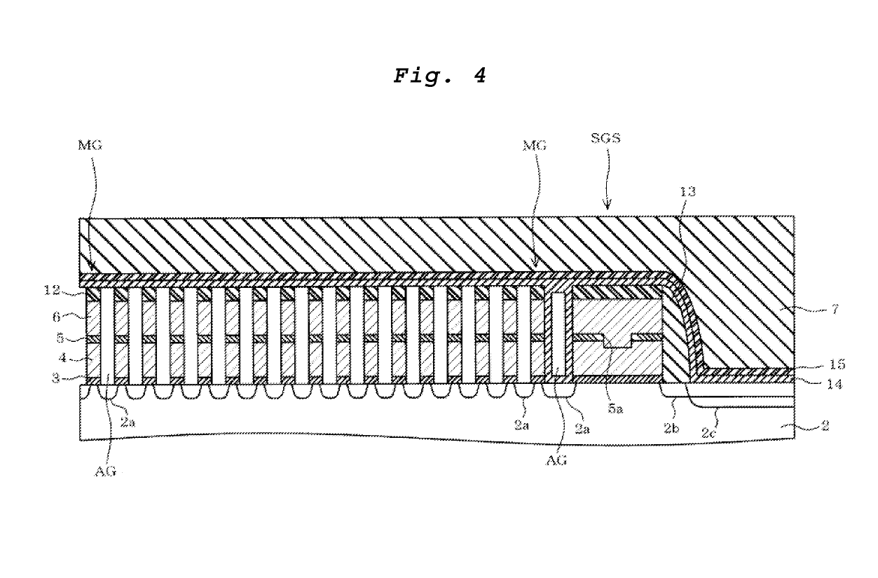

The source/drain regions 2a are formed on the surface layer of the silicon substrate 2 located between the gate electrodes MG-MG and between the gate electrodes SGS (or SGD)-MG. An LDD (lightly doped drain) regions 2b corresponding to the drain regions are arranged on the outer layer of the silicon substrate 2 located between the gate electrodes SGS-SGS and between the gate electrodes SGD-SGD. The source/drain regions 2a and the LDD regions 2b can be formed by introducing impurity into the surface layer of the silicon substrate 2. Also, a source region 2c or drain region 2c (see FIG. 4) having the high concentration impurity fed thereinto is formed on the surface layer of the silicon substrate 2 located between the gate electrodes SGS-SGS and between the gate electrodes SGD-SGD. In this way, the LDD structure is formed.

The gate electrodes SGS and SGD of the first select gate transistor Trs1 and second select gate transistor Trs2 are schematically shown in FIG. 3. The polysilicon film 4, the inter-electrode insulating film 5, and the polysilicon film 6 are laminated on almost the same structure as the gate electrode MG of the memory cell transistor Trm. On the gate electrode SG, at the central portion of the inter-electrode insulating film 5, as shown in FIG. 4, an opening 5a (see FIG. 4) is formed, so that the polysilicon films 4 and 6 are in electrical contact with each other and therefore the select gate transistors Trs1 and Trs2 function as conventional transistors having no floating gate electrode.

On the upper side of the gate electrodes MG, SGS, and SGD, an insulating film 7, such as a silicon oxide film or the like, is formed as the interlayer insulating film for insulation between the gate electrodes. Although not shown in FIG. 3, an air gap structure (see FIG. 4) is adopted where air gaps AG (air gap portions) are formed without the insulating film 7 between the gate electrodes MG-MG, between MG-SGS, and between MG-SGD.

A source contact 8 is arranged through the insulating film 7 so that the source regions 2c between the gate electrodes SGS-SGS are brought into contact with each other. The source contact 8 is in contact with the source line SL shown in FIG. 2A, and it is formed to connect the source regions 2c of the first select gate transistors Trs1 adjacent each other via the element separating region Sb. Also, a bit line contact 9 is arranged through the insulating film 7 so that it contacts the drain regions 2c between the gate electrodes SGD-SGD. Here, the bit line contacts 9 correspond to the bit line contacts CBa and CBb shown in FIG. 2A.

On the insulating film 7, a first embedded wiring layer 10 and a second embedded wiring layer 11 are formed as two separate layers. The first embedded wiring layer 10 is formed on the insulating film 7 on the upper side of the gate electrodes MG, SGS and SGD. The second embedded wiring layer 11 is formed on the insulating film 7 on the upper side of the first embedded wiring layer 10.

As shown in FIG. 2B, the first embedded wiring layer 10 has various portions, including a source line 10a, a wiring pattern portion 10b, a dummy pattern portion 10c, and a connecting portion 10d. The source line 10a is located on the upper side of the source contact 8 and is formed in an electrically connecting state, and is formed extending in the same general direction as that of the word line WL located in the lower layer.

Several wiring pattern portions 10b are formed in a region with a prescribed width adjacent to the source line 10a and contact to the source line 10a. The wiring pattern portions 10b are formed extending in generally the same direction as the word lines WL located in the lower layer. However, the wiring pattern portions 10b include branch portions 10bb formed obliquely from the primary section of the wire. The branch portions 10bb are formed at an angle about 45° with respect to the word lines WL (in a plane generally parallel with the plane in which the word lines WL are formed). They are formed to be in a direction not orthogonal to the direction in which the word lines WL are formed.

Also, connecting portions 10d-1 formed at the same angle as that of the branch portions 10bb. The connecting portions 10d are connected electrically between the source lines 10a and the wiring pattern portion 10b. Other connecting portions 10d-2 also connect different portions of the wiring pattern portions 10b in the direction orthogonal to the word lines WL. Here, the pattern of the connecting portion between wiring pattern portions 10b-2 is an arc shape, and there exists no pattern edge of the connecting portion that is orthogonal to the word lines WL. In addition, in the wiring pattern portion 10b, several contact portions 10e are arranged corresponding to the portions where the NAND cell units SU on the lower layer are arranged as the dummy pattern. The contact pattern is connected so that power supply is received from the wiring layer arranged on the upper side with respect to the second embedded wiring layer 11.

Also, the dummy pattern portions 10c are formed in a prescribed range or ranges on the two sides excluding the portions of the bit line contacts 9. These dummy pattern portions 10c are formed in the direction generally parallel with the direction of formation of the word lines WL, and they have the connecting portions 10cc formed at an angle partially in the direction where they cross the word lines WL obliquely rather than orthogonally. The connecting portions 10cc are formed as an angled pattern having a angle of about 45° with respect to the direction of formation of the word lines WL. Also, for the entirety, the dummy pattern portion 10c has no electrically connected portion, and it is in the electrically floating state.

As a result, the first embedded wiring layer 10 is formed as a pattern with a nearly even coating (a similar pattern loading) for the entirety of the upper surface of the insulating film 7. For the source line 10a, in order to decrease the resistance, the wiring pattern portion 10b is arranged in a region with a prescribed width around the source line 10a at the center, and they are electrically connected by the connecting portion 10d to decrease the wiring resistance. Also, the dummy pattern portion 10c is formed around the portion where the bit line contact 9 is formed at the center and until the boundary portion with the wiring pattern portion 10b.

As shown in FIG. 3, the second embedded wiring layer 11 is formed in the same direction as the direction for forming the element region Sa or the NAND cell unit SU, that is, in the Y-direction. The second embedded wiring layer portions are formed side by side for each bit line contact 9 (CBa and CBb). The second embedded wiring layer 11 functions as the bit line BL, and it is formed in the direction generally perpendicular to the source line 10a of the first embedded wiring layer 10. Also, on the second embedded wiring layer 11, the bit line BL is not formed in the portion where the NAND cell unit SU is not formed. In this portion, the wiring layer of the upper layer and the contact portion 10e arranged on the wiring pattern portion 10b of the first embedded wiring layer 10 of the lower layer are connected with each other by a connecting plug.

In a NAND-type flash memory with smaller device features, in order to decrease the interference between the adjacent cells, an air gap AG is arranged between the gate electrodes MG-MG. In this way, it is possible to minimize the rupture due to stress on the portion where the air gap AG is formed as to be described later in a manufacturing operation.

In addition, it is possible to feed power from the contact portion 10e to the wiring pattern portion 10b of the first embedded wiring layer 10. Consequently, it is possible to decrease the resistance and thereby to suppress delay in device operation caused by the resistance.

In the following, an example of the manufacturing method of the constitution will be explained with reference to FIG. 4 to FIG. 8. Here, only certain steps of the method are specifically described and other additional steps will be readily apparent to those skilled in the art. However, other steps of operations may be added as the conventionally adopted steps of operation, or some steps of operation may be deleted. In addition, various steps of operation may be appropriately interchanged.

The steps of operation until the state shown in FIG. 4 will be explained. The gate insulating film 3 and the polysilicon film 4 as the material for the floating gate electrode are formed on the silicon substrate 2. Then, the polysilicon film 4 and the upper side of the silicon substrate 2 are patterned by, for example, a photolithographic technology, and etching is carried out to form element separating trenches in FIGS. 2A and 2B. Then, by burying the element isolation insulating film (not shown in the drawing) in the trenches, the element region Sa and element separating region Sb are formed.

Then, on the polysilicon film 4, the inter-electrode insulating film 5 is formed as ONO (oxide-nitride-oxide) film or the like. Then, the polysilicon film 6 is formed as the material of the control gate electrode on the inter-electrode insulating film 5. In this case, in the portions where the gate electrodes of the transistors of the gate electrodes SGS and SGD of the first select gate transistor Trs1 and second select gate transistor Trs2, the opening 5a is formed on the inter-electrode insulating film 5, forming the state in which the polysilicon films 4 and 6 are in contact with each other. An insulating film 12 for processing is formed on the polysilicon film 6.

Then, by the photolithographic technology, the line-and-space pattern is formed in the memory cell region, and, the prescribed resist pattern is formed in the peripheral circuit region. With the resist pattern as a mask, the insulating film 12 is etched to form a hard mask.

Then, the polysilicon film 6, the inter-electrode insulating film 5, the polysilicon film 4, and the gate insulating film 3 are subject to anisotropic etching processing so that the gate electrodes MG and the gate electrodes SGS and SGD are formed separated from each other. Then, with the insulating film 12 of the gate electrodes MG, SGS and SGD as a mask, the n-type impurity (such as phosphorus) is fed into the surface layer of the silicon substrate 2 by a conventional ion implanting method, followed by heat treatment, to form the source/drain regions 2a and the LDD regions 2b (the same for the source regions).

Then, a sacrificial film is formed between the gate electrodes MG-MG, between the gate electrodes MG-SGS, and between the gate electrodes MG-SGD. In addition, a spacer 13 is formed on the side walls of the gate electrodes SGS and SGD between the gate electrodes SGS-SGS and between SDS-SDS. With this spacer 13 as a mask, the impurity at a high concentration is fed into the surface layer of the silicon substrate 2 between the gate electrodes SGS-SGS and between SGD-SGD to form the source regions (drain regions) 2c. As a result, an LDD structure is formed.

Then, the sacrificial film is removed, so that air gaps AG between the gate electrodes MG-MG and between MG-SGS and between MG-SGD are formed. Then, their upper end of the air gap is capped by forming a silicon oxide film 14 and a silicon nitride film 15 as the liner film. Then, a silicon oxide film is formed as the insulating film 7 so that the interlayer insulating film embeds the concave portions between the gate electrodes SGS-SGS and between SGD-SGD. As a result, the structure shown in FIG. 4 is obtained.

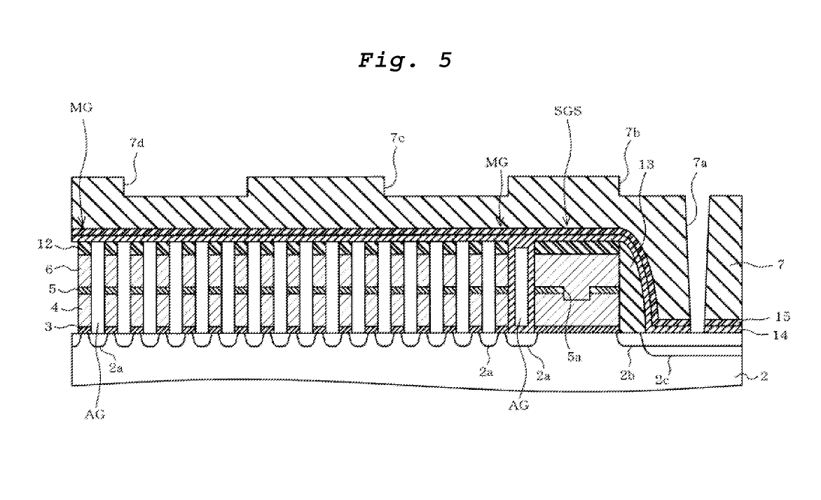

In the following, explanation will be made on the operation whereby the first embedded wiring layer 10 is formed on the upper surface of the insulating film 7. As shown in FIG. 5, using for example a photolithographic technology, pattern trenches 7b to 7d are formed for forming the various patterns of the contact trenches 7a for the source contact 8 and the first embedded wiring layer 10. Here, the contact trenches 7a are formed by etching from the upper surface of the insulating film 7 through to reach the upper surface of the source region (drain region) 2c between the gate electrodes SGS-SGS and between SGD-SGD. Also, pattern trenches 7b to 7d are formed by etching the insulating film 7 from the upper surface until a prescribed depth is achieved.

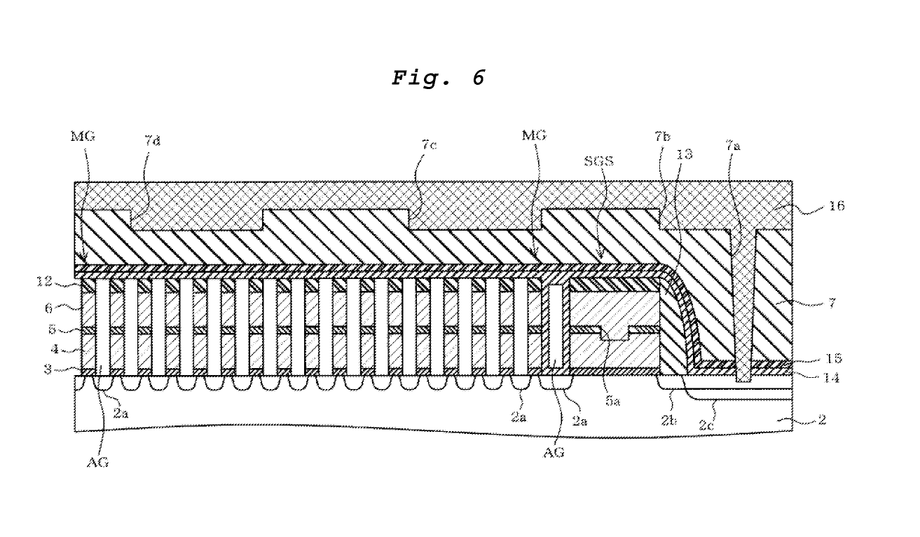

As shown in FIG. 6, a metal film 16 made of, for example, tungsten (W) is formed on the entire surface for the first embedded wiring layer 10. In this case, the metal film 16 fills up the interior of the contact trenches 7a for the source contact 8 and the pattern trenches 7b to 7d for forming the various patterns of the first embedded wiring layer 10, and, at the same time, it also covers the upper surface of the remaining portion of the insulating film 7.

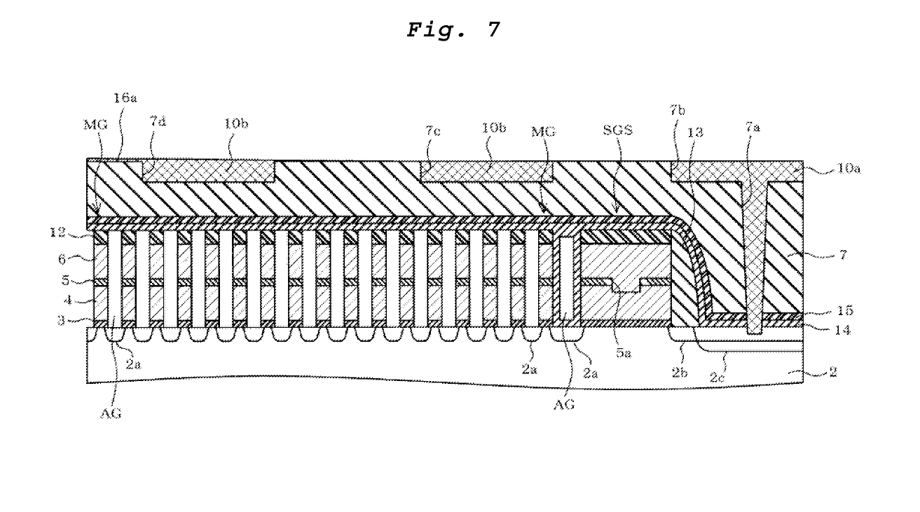

As shown in FIG. 7, the metal film 16 formed over the upper surface of the insulating film 7 is removed by CMP treatment. In the CMP treatment, as the metal film 16 is removed by polishing, because there is a difference in the torque in polishing between the metal film 16 and the insulating film 7, such change is detected to determine the end of the CMP treatment. More specifically, because the torque for the silicon oxide film or other insulating film 7 is lower than that of the metal film 16, this fact can be adopted in detecting the end of the polishing operation. However, in the actual operation, for the large diameter wafer for forming several semiconductor devices, difference in the polishing degree may take place. Consequently, even when the end of the polishing is detected, due to the dispersion, some residual portions 16a after polishing may be left for the metal film 16 on the insulating film 7. Also, in the case shown in the drawing, in order to facilitate explanation, generation of dispersion in polishing is shown as taking place in one semiconductor device. However, in the practice, such state generally takes place at sites far away from each other on the wafer.

In consideration of generation of dispersion in polishing in the CMP treatment as mentioned previously, after detecting the end of polishing, over treatment is carried out to ensure reliable removal of the residual portions 16a. In this case, because the metal film 16 has a lower polishing rate than the insulating film 7, a concave shape may be formed in the insulating film 7. Consequently, the slurry in the CMP treatment is left in the concave portion of the insulating film 7, and a stress is generated. That is, during the process of the CMP treatment, a high stress is results from the over treatment process used to ensure residual metal (film 16a) is removed sufficiently.

According to the present disclosure, it has been determined that an especially high shear stress is generated due to the difference in the frictional force between the metal film 16 and the insulating film 7 when the polishing slurry stagnates in the orthogonal pattern portions (i.e., right-angle corners in the pattern). Thus, by forming the air gap AG between the gate electrodes MG-MG formed in the lower layer of the insulating film 7 when the pattern of the wiring layer formed by the metal film 16 is orthogonal to the word lines WL, then in the CMP treatment process since compression and shear stress applied on the lower layer are high, the pattern structure of the gate electrodes MG where the air gap AG is formed may be crushed.

In consideration of this problem, according to the present embodiment, as the first embedded wiring layer 10, a planar pattern shown in FIG. 2B is formed to minimize the presence of orthogonal patterns in the wiring layer. As a result, the slurry used in the CMP treatment can be exhausted more easily from the non-orthogonal pattern portions of the first embedded wiring layer 10 and thus, it is possible to prevent damage from partial stagnation. Consequently, it is possible to suppress stagnation of the slurry and to suppress increase in the shear stress. As a result, it is possible to prevent rupture of the pattern of the gate electrodes MG that form the air gap AG.

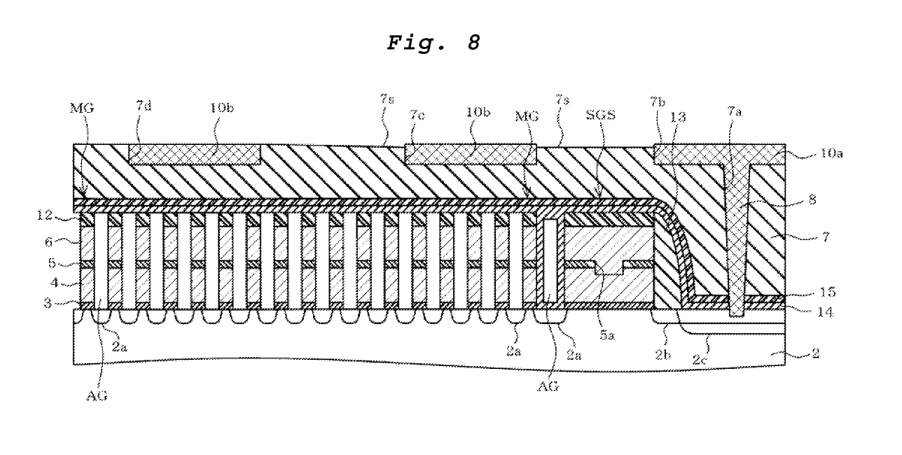

As explained above, as shown in FIG. 8, as the first embedded wiring layer 10, by arranging the source lines 10a, the wiring pattern portions 10b, the dummy pattern portions 10c, the connecting portions 10d, and the branch portions 10bb, it is possible to limit stagnation of the slurry in the pattern of the first embedded wiring layer 10 during the CMP treatment, and, therefore, to suppress an increase in the shear stress during the over treatment CMP process, and thereby to suppress pattern rupturing of the lower layer portion.

Then, on the upper surface of the first embedded wiring layer 10, the insulating film 7 is formed as the interlayer insulating film, and contact holes are formed from the upper surface to the surface of the drain regions 2c between the gate electrodes SGD-SGD. In addition, the wiring trench portions are formed for forming the second embedded wiring layer 11 as the bit line. Then, just as mentioned previously, a metal film is formed on the entire surface, and it is polished by the CMP treatment so that the metal film is left in the wiring trench positions and the contact holes. As a result, the second embedded wiring layer 11 and the contact plugs 9 are formed. Then, a multilayer wiring structure can be formed on the upper layer. As a result, the NAND-type flash memory device 1 is obtained.

According to the present embodiment, the pattern of the first embedded wiring layer 10 is formed to minimize the portions which cross orthogonal to the word lines WL, so that when the CMP treatment is carried out in the formation operation, it is possible to minimize the adverse influence of the shear stress on the constitution of the air gap AG formed in the lower layer, and it is thus possible to suppress generation of rupture of the pattern.

In addition, as the wiring pattern 10b is arranged in the region with a prescribed width on the two sides of the source line 10a, and connection is made by the connecting portions 10d, it is possible to alleviate delay in wiring caused by fall in the voltage of the source line 10a, and it is possible to improve the electric characteristics.

### Other Embodiments

The following modifications can be adopted.

One may also adopt a scheme in which the air gap AG is also adopted in separating the elements of the element regions Sa.

The pattern of the first embedded wiring layer 10 can have the design changed appropriately so that there is no component orthogonal to the word lines WL. Also, in the above, the inclined angle of the inclined pattern is 45°. However, one may also adopt a scheme in which any appropriate angle is adopted as long as there is no portion formed orthogonal to the word lines WL.

The ratio of the wiring pattern portion 10b and the dummy pattern portion 10c of the first embedded wiring layer 10 can be varied.

In the above, the present disclosure is adopted in the NAND-type flash memory device 1. However, it is also possible to adopt in the NOR-type flash memory device, EEPROM or other nonvolatile semiconductor memory devices.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A nonvolatile semiconductor memory device, comprising:
a memory cell array including a plurality of memory cell units arrayed in a matrix configuration along a first direction and a second direction which is perpendicular direction to the first direction, each memory cell unit including a plurality of memory cell transistors connected in series, a first select gate transistor connected to a first end of the memory cell unit, and a second select gate transistor connected to a second end of the memory cell unit word lines extending to the first direction, each of which is commonly connected to control gate electrodes of memory transistors disposed to the first direction, and
a first insulating film formed on an upper surface of the memory cell array,
a first embedded wiring layer embedded in the first embedded wiring layer, the first embedded wiring layer including a wiring portion commonly connected to a source region of each first select gate transistor,
wherein the first embedded wiring layer has an inclined pattern in which extends in a direction not parallel to either the first and the second direction.

2. The memory device of claim 1, wherein one the inclined pattern extends towards the first direction at a 45° angle.

3. The memory device of claim 1, wherein the first embedded wiring layer has a connecting portion which has arc-shape.

4. The memory device of claim 1, wherein the memory cell array includes an air gap formed between an adjacent pair of memory cell transistors.

5. The memory device of claim 4, wherein the air gap is formed between a memory cell transistor and the first selection gate transistor.

6. The memory device of claim 1, wherein the first embedded wiring layer further includes a dummy portion formed in an electrically floating state.

7. The memory device of claim 6, wherein the dummy pattern portion is disposed in the region with a prescribed width around the upper side of the drain of the second select gate transistor as the center.

8. The memory device of claim 7, wherein the inclined pattern is electrically connected to a source of a first select gate transistor and formed with a prescribed width around an upper side of the source of the first select gate transistor as the center.

9. The memory device of claim 1, further comprising:
a second insulating film formed on an upper surface of the first embedded wiring layer; and
a second embedded wiring layer embedded in the second insulating film,
wherein the first embedded wiring layer includes contacts through which power is supplied from a wiring layer above second embedded wiring layer.

10. A nonvolatile semiconductor memory device, comprising:
a memory cell array having a plurality of memory cell transistors connected in series to a first direction, a first select gate transistor disposed adjacent to one of the memory cell transistor to a second direction which is perpendicular direction to the first direction; and
a first embedded wiring layer embedded in a first insulating film formed on the memory cell transistors, the first embedded wiring including a portion commonly connected to the sources of the first select gate transistors,
wherein the first embedded wiring layer has a pattern in which substantially all pattern edges which intersect the first direction are not parallel to the second direction.

11. The device of claim 10, wherein the first embedded wiring layer has a similar pattern loading across the upper surface of the memory cell transistors.

12. The device of claim 10, wherein a wiring connection in the wiring pattern portion is made in an arc-shaped pattern.

13. The device of claim 10, wherein a wiring connection in the wiring pattern portion is made at a 45° oblique angle to the first direction.

14. The device of claim 10, wherein the first embedded wiring layer includes a plurality of contact portions.

15. A manufacturing method of a nonvolatile semiconductor memory device, the method comprising:
forming a memory cell array having a plurality of memory cell units arrayed in a matrix in a first direction and a second direction, each memory cell unit having a plurality of memory cell transistors connected in series, a first select gate transistor connected to a first end of the memory cell unit, and a second select gate transistor connected to a second end of the memory cell unit;
forming a first insulating film on an upper surface of the memory cell array;
forming trenches in the first insulating film, the trenches formed an inclined pattern which extends in a direction not parallel to either of the first and the second directions;
forming a metal film on the first insulating film, the metal film filling the trenches; and
polishing the metal film to remove the metal film except portions in the trenches.

16. The method of claim 15, wherein the memory cell array includes an air gap between an adjacent pair of memory cell transistors.

17. The method of claim 15, wherein the polishing of the metal film includes a chemical mechanical polishing process.

18. The method of claim 15, wherein at least one trench formed in the first insulating layer extends generally in the first direction and includes a plurality of branch portions which intersect the first direction at an approximately 45° angle.
